(19) United States
(12) Patent Application Publication
(10) Pub. No.: US 2026/0011379 A1
(43) Pub. Date: Jan. 8, 2026

(54) OPERATING METHOD FOR MEMORY, MEMORY AND MEMORY SYSTEM

(71) Applicant: YANGTZE MEMORY TECHNOLOGIES CO., LTD., Wuhan (CN)

(72) Inventors: Ting ZHU, Wuhan (CN); TingTing WANG, Wuhan (CN); Bin LIU, Wuhan (CN)

(21) Appl. No.: 19/055,250

(22) Filed: Feb. 17, 2025

(30) Foreign Application Priority Data
Jul. 2, 2024 (CN) 202410881902.4

(51) Int. Cl. G11C 16/32; G11C 16/16

(52) U.S. Cl. CPC G11C 16/32; G11C 16/16

(57) ABSTRACT

The present disclosure includes an operating method for memory, a memory and a memory system, belonging to the field of storage technology. In this method, in a process of performing a pre-program operation on a memory block to be erased, if a suspend command for suspending the pre-program operation is received, the pre-program operation is not immediately suspended in the case that the pre-program operation has not been performed for a certain duration, and the pre-program operation is suspended to response to the suspend command only when the pre-program operation has been performed for a certain duration.

### CROSS-REFERENCE TO RELATED APPLICATIONS

This application claims the benefit of priority to Chinese Application No. 202410881902.4, filed on Jul. 2, 2024, which is incorporated herein by reference in its entirety.

### TECHNICAL FIELD

The present application relates to the field of storage technology, and in particular to an operating method for memory, a memory and a memory system.

### BACKGROUND

A memory supports various operations such as programmed operation, erase operation, and read operation, wherein erase operation also includes multiple sub-operations, e.g., pre-program operation, erase sub-operation, and erase verification operation. Each sub-operation process in the erase operation also supports a suspend command and a resume command.

### SUMMARY

According to one aspect of the present disclosure, a method for operating a memory is provided, the method may include performing a pre-program operation on a memory block to be erased in a memory; obtaining a suspend command for suspending the pre-program operation; and suspending the pre-program operation in response to the pre-program operation having been performed for a first duration, wherein the first duration may be less than or equal to a total duration required to complete the performing of the pre-program operation.

In some implementations, the suspending the pre-program operation in response to the pre-program operation having been performed for a first duration may include suspending the pre-program operation in response to a duration for which the pre-program operation having been performed being equal to the first duration; and continuing to perform the pre-program operation in response to the duration for which the pre-program operation having been performed being less than the first duration, until the duration for which the pre-program operation has been performed may be equal to the first duration, and suspending the pre-program operation.

In some implementations, the pre-program operation process corresponds to N first durations, where N may be an integer greater than or equal to 1.

In some implementations, the pre-program operation process includes N time windows, a total duration of first i time windows among the N time windows comprise a first duration, and i may be an integer greater than or equal to 1 and less than or equal to N.

In some implementations, if N may be greater than 1, each of the durations of first N−1 time windows among the N time windows comprise a second duration, and the duration of the last time window among the N time windows comprise a third duration, and the third duration may be less than or equal to the second duration.

In some implementations, after the obtaining the suspend command for suspending the pre-program operation, the method further comprises: determining whether the pre-program operation has been performed for the first duration, based on the second duration and the duration for which the pre-program operation has been performed.

In some implementations, after the suspending the pre-program operation, the method further comprises: obtaining a resume command for resuming the pre-program operation; compensating a remaining duration of the pre-program operation based on a compensation duration to obtain a compensated remaining duration, wherein the remaining duration refers to the duration for which the pre-program operation has not been performed; and performing the pre-program operation according to the compensated remaining duration.

In some implementations, before the compensating a remaining duration of the pre-program operation based on a compensation duration to obtain the compensated remaining duration, the method further comprises: determining the compensation duration based on the number of pre-programmed planes of the memory at current time, wherein the number of pre-programmed planes refers to the number of planes in the memory that are in the pre-program operation process, and the planes include one or more memory blocks.

In some implementations, the number of pre-programmed planes may be in positive correlation with compensation time.

According to another aspect of the present disclosure, an operating method for memory is provided, the method includes: obtaining a resume command for resuming a pre-program operation; compensating a remaining duration of the pre-program operation based on a compensation duration to obtain the compensated remaining duration, wherein the remaining duration refers to the duration for which the pre-program operation has not been performed; and performing the pre-program operation on a memory block to be erased in a memory according to the compensated remaining duration.

In some implementations, before the compensating a remaining duration of the pre-program operation based on a compensation duration to obtain the compensated remaining duration, the method further comprises: determining the compensation duration based on the number of pre-programmed planes of the memory at current time, wherein the number of pre-programmed planes refers to the number of planes in the memory that are in the pre-program operation process, and the planes include one or more memory blocks.

In some implementations, the number of pre-programmed planes may be in positive correlation with compensation time.

In some implementations, before the obtaining a resume command for resuming a pre-program operation, the method further comprises: performing the pre-program operation on the memory block to be erased; obtaining a suspend command for suspending the pre-program operation; and suspending the pre-program operation in response to the pre-program operation having been performed for a first duration, the first duration being less than or equal to a total duration required to complete the performing of the pre-program operation.

In some implementations, the suspending the pre-program operation in response to the pre-program operation having been performed for a first duration includes: suspending the pre-program operation in response to a duration for which the pre-program operation having been performed being equal to the first duration; and continuing to perform the pre-program operation in response to the duration for which the pre-program operation having been performed being less than the first duration, until the duration for which the pre-program operation has been performed may be equal to the first duration, and suspending the pre-program operation.

In some implementations, the pre-program operation process corresponds to N first durations, where N may be an integer greater than or equal to 1.

In some implementations, the pre-program operation process includes N time windows, a total duration of first i time windows among the N time windows may be a first duration, and i may be an integer greater than or equal to 1 and less than or equal to N.

In some implementations, if N may be greater than 1, each of the durations of first N−1 time windows among the N time windows comprise a second duration, and the duration of the last time window among the N time windows comprise a third duration, and the third duration may be less than or equal to the second duration.

In some implementations, before the compensating a remaining duration of the pre-program operation based on a compensation duration to obtain the compensated remaining duration, the method further comprises: determining whether the pre-program operation has been performed for the first duration, based on the second duration and the duration for which the pre-program operation has been performed.

According to another aspect of the present disclosure, a memory is provided, the memory comprises a memory block and a peripheral circuit, the memory block is configured to store data, the memory block is coupled to the peripheral circuit through a word line, and the peripheral circuit is configured to: perform a pre-program operation on a memory block to be erased in the memory; obtain a suspend command for suspending the pre-program operation; and suspend the pre-program operation in response to the pre-program operation having been performed for a first duration, the first duration being less than or equal to a total duration required to complete the performing of the pre-program operation.

In some implementations, the peripheral circuit is further configured to: suspend the pre-program operation in response to a duration for which the pre-program operation having been performed being equal to the first duration; and continue to perform the pre-program operation in response to the duration for which the pre-program operation having been performed being less than the first duration, until the duration for which the pre-program operation has been performed may be equal to the first duration, and suspend the pre-program operation.

In some implementations, the pre-program operation process corresponds to N first durations, where N may be an integer greater than or equal to 1.

In some implementations, the pre-program operation process includes N time windows, a total duration of first i time windows among the N time windows comprise a first duration, and i is an integer greater than or equal to 1 and less than or equal to N.

In some implementations, if N may be greater than 1, each of the durations of first N−1 time windows among the N time windows comprise a second duration, and the duration of the last time window among the N time windows comprise a third duration, and the third duration may be less than or equal to the second duration.

In some implementations, the peripheral circuit is further configured to: determine whether the pre-program operation has been performed for the first duration, based on the second duration and the duration for which the pre-program operation has been performed.

In some implementations, the peripheral circuit includes a first register, and the first register is configured to store the second duration.

In some implementations, the peripheral circuit is further configured to: obtain a resume command for resuming a pre-program operation; compensate a remaining duration of the pre-program operation based on a compensation duration to obtain the compensated remaining duration, wherein the remaining duration refers to the duration for which the pre-program operation has not been performed; and perform the pre-program operation according to the compensated remaining duration.

In some implementations, the peripheral circuit includes a second register, and the second register is configured to store the compensation duration.

In some implementations, the peripheral circuit is further configured to: determine the compensation duration based on the number of pre-programmed planes of the memory at current time, wherein the number of pre-programmed planes refers to the number of planes in the memory that are in the pre-program operation process, and the planes include one or more memory blocks.

In some implementations, the number of pre-programmed planes is in positive correlation with compensation time.

According to another aspect of the present disclosure, a memory system is provided, the memory system comprises a memory controller and a memory, the memory controller is coupled to the memory and configured to control the memory. The memory comprises a memory block and a peripheral circuit, the memory block is configured to store data, the memory block is coupled to the peripheral circuit through a word line, and the peripheral circuit is configured to: perform a pre-program operation on a memory block to be erased in the memory; obtain a suspend command for suspending the pre-program operation; and suspend the pre-program operation in response to the pre-program operation having been performed for a first duration, the first duration being less than or equal to a total duration required to complete the performing of the pre-program operation.

In some implementations, the peripheral circuit is further configured to: suspend the pre-program operation in response to a duration for which the pre-program operation having been performed being equal to the first duration; and continue to perform the pre-program operation in response to the duration for which the pre-program operation having been performed being less than the first duration, until the duration for which the pre-program operation has been performed is equal to the first duration, and suspend the pre-program operation.

In some implementations, the pre-program operation process corresponds to N first durations, where N may be an integer greater than or equal to 1.

In some implementations, the pre-program operation process includes N time windows, a total duration of first i time windows among the N time windows comprise a first duration, and i may be an integer greater than or equal to 1 and less than or equal to N.

In some implementations, if N may be greater than 1, each of the durations of first N−1 time windows among the N time windows comprise a second duration, and the duration of the last time window among the N time windows comprise a third duration, and the third duration may be less than or equal to the second duration.

In some implementations, the peripheral circuit is further configured to: determine whether the pre-program operation has been performed for the first duration based on the second duration and the duration for which the pre-program operation has been performed.

In some implementations, the peripheral circuit includes a first register, and the first register is configured to store the second duration.

In some implementations, the peripheral circuit is further configured to: obtain a resume command for resuming the pre-program operation; compensate a remaining duration of the pre-program operation based on a compensation duration to obtain the compensated remaining duration, wherein the remaining duration refers to the duration for which the pre-program operation has not been performed; and perform the pre-program operation according to the compensated remaining duration.

In some implementations, the peripheral circuit includes a second register, and the second register is configured to store the compensation duration.

In some implementations, the peripheral circuit is further configured to: determine the compensation duration based on the number of pre-programmed planes of the memory system at current time, wherein the number of pre-programmed planes refers to the number of planes in the memory system that are in the pre-program operation process, and the planes include one or more memory blocks.

In some implementations, the number of pre-programmed planes may be in positive correlation with compensation time.

In a process of performing a pre-program operation on a memory block to be erased, if a suspend command for suspending the pre-program operation is received, the pre-program operation is not immediately suspended in the case that the pre-program operation has not been performed for a certain duration (e.g., a first duration), and the pre-program operation is suspended to response to the suspend command only when the pre-program operation has been performed for a certain duration, and therefore, the response time of the suspend command in the pre-program operation process is increased, and the number of suspension of the pre-program operation is reduced, thereby improving the reliability and performance of the memory reduced due to multiple suspensions of the pre-program operation.

### BRIEF DESCRIPTION OF THE DRAWINGS

FIG. 1 shows a schematic diagram of an application environment of a memory system, according to an exemplary implementation;

FIG. 2 shows a schematic diagram of a memory according to an exemplary implementation;

FIG. 3 shows a schematic diagram of an electrical structure of a memory array according to an exemplary implementation;

FIG. 4 shows a structure diagram of a peripheral circuit according to an exemplary implementation;

FIG. 5 shows a waveform diagram of a pre-program pulse voltage according to an exemplary implementation;

FIG. 6 shows a schematic diagram illustrating a relationship between the number of pre-programmed planes and a WL voltage according to an exemplary implementation;

FIG. 7 shows a flowchart of an operating method for memory according to an exemplary implementation;

FIG. 8 is a waveform diagram of a pre-program pulse voltage in a pre-program operation process according to an exemplary implementation;

FIG. 9 shows a flowchart of performing a pre-program operation during an erase operation according to an exemplary implementation;

FIG. 10 shows a flowchart of another operating method for memory according to an exemplary implementation.

### DETAILED DESCRIPTION

In order to make the purpose, technical solution and advantages of the present disclosure clearer, implementations of the present disclosure will be further described in detail below in conjunction with the accompanying drawings.

In the present disclosure, the terms “first”, “second” or the like are configured to distinguish the same or similar items that have substantially the same effect and function, and it is understood that there is no logical or temporal dependence between the “first”, “second” and “n-th”, nor limits on number or performing order. It is also understood that, although the following description uses the terms first, second, etc., to describe various elements, these elements should not be limited by the terms.

These terms are only configured to distinguish one element from another. For example, a first element could be termed a second element, and similarly, a second element could be termed a first element, without departing from the scope of various examples herein. Both the first element and the second element may be elements, and in some cases, may be separate and distinct elements.

The term “at least one” refers to “one or more”, e.g., at least one element may be any integer number of elements greater than or equal to one, such as one element, two elements, three elements, etc. The term “at least two” refers to “two or more”, e.g., at least two elements may be any integer number of elements greater than or equal to two, such as two elements, three elements, etc.

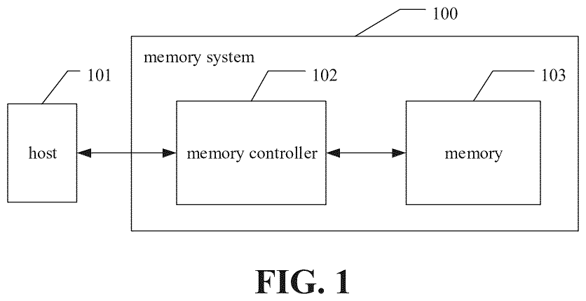

FIG. 1 shows a schematic diagram of an application environment of a memory system according to an exemplary implementation. The application environment includes a memory system 100 and a host 101, where the host 101 may be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having memory device therein. According to the interface protocol between the memory system 100 and the host 101, the memory system 100 may be configured as a universal flash storage (UFS) device, a solid state drive (SSD), a multimedia card (MMC), a secure digital (SD) card, a Computer Memory Card International Association (PCMCIA) card type storage device, a Peripheral Component Interconnect (PCI) type storage devices, a PCI Express (PCI-E) type storage device, a Compact Flash (CF) card, a smart media card or a memory stick, etc., wherein a multimedia card (MMC) is e.g., an embedded multimedia card (eMMC), small size multimedia card (RS-MMC) or micro MMC, etc., and a SD card is e.g., a mini SD or a micro SD.

The host 101 may control the operation of the memory system 100. For example, the host 101 may control the operation of the memory system 100 through instructions, e.g., the host 101 sends instructions to the memory system 100, and the memory controller 102 performs corresponding operations (e.g., operations such as data program, data read and data erase, or other operations) in response to the instructions of the host 101. In some implementations, the host 101 may include a host processor and a host memory, and the host processor may control the operation of the host 101. For example, the host processor may interact with the memory system 100 through a storage driver to control the operation of the memory system 100. The storage driver may be a software module configured to control the memory system 100, and the storage driver may also load a mapping table into the host memory to increase the speed at which the host processor controls the memory system 100 to perform a read operation.

The memory system 100 may store data accessed by the host 101, and the host 101 may be configured to send the data to the memory system 100. Alternatively, the host 101 may be configured to receive data from the memory system 100.

As shown in FIG. 1, the memory system 100 includes a memory controller 102 and a memory 103, wherein there is at least one memory 103, and the memory 103 is a storage medium configured to store data in the memory system 100, the memory 103 is e.g., a NAND flash memory device, a three-dimensional (3D) NAND flash memory device, etc.

The memory controller 102 may control the memory 103. In FIG. 1, the memory controller 102 is deployed outside the host 101, the memory controller 102 is coupled to the host 101 and communicates with the host 101, and the memory controller 102 and the memory 103 are integrated into the memory system 100. In other implementations, the memory controller 102 is not integrated into the memory system 100, and the memory controller 102 is integrated in the host 101, and the memory controller 102 in the host 101 communicates with the memory 103 outside the host 101 to control the memory 103. In other implementations, part of functional modules of the memory controller 102 are integrated into the host 101, and the other part of the functional modules are integrated into the memory system 100. These two parts of functional modules cooperate with each other to control the memory 103. For example, functions such as front end (FE) and flash translation layer (FTL) or the like of the memory controller 102 are integrated into the host 101, and functions such as back end (BE) of the memory controller 102 are integrated into the memory system 100; or the FE function of the memory controller 102 is integrated into the host 101, and functions such as FTL and BE or the like of the memory controller 102 are integrated into the memory system 100.

The memory controller 102 is also coupled to the memory 103, manages data stored in the memory 103, and is responsible for data scheduling between the memory 103 and the host 101. The memory controller 102 may be configured to control operations of the memory 103, e.g., read operation, erase operation, and program operation. The memory controller 102 may also be configured to manage various functions related to data stored or to be stored in memory 103, including but not limited to bad block management, garbage collection, logical-to-physical address translation, wear leveling, etc. The memory controller 102 may also perform any other suitable functions, e.g., formatting memory 103.

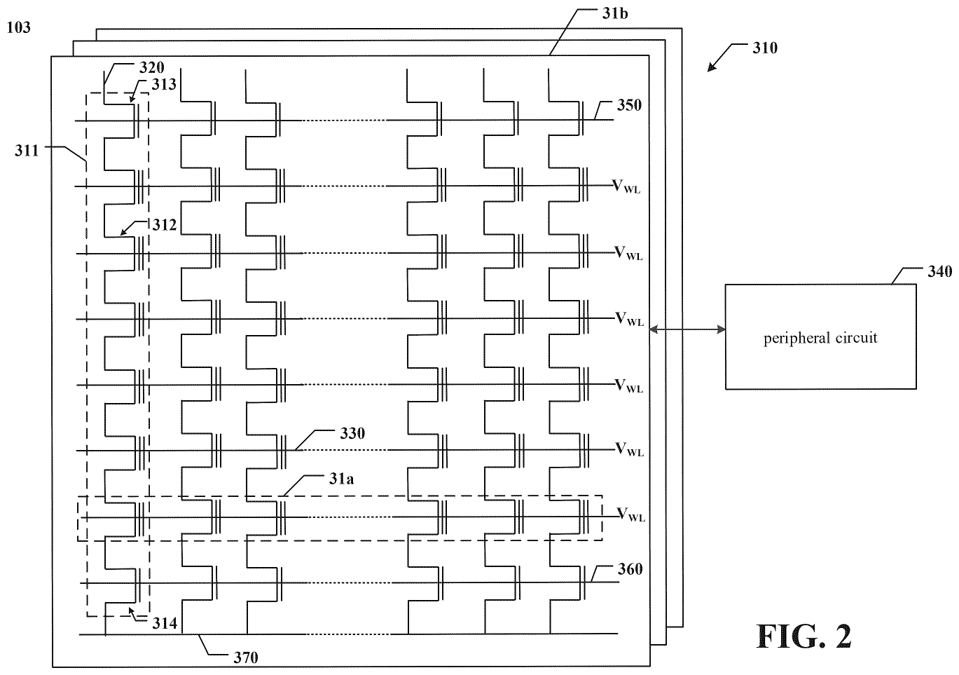

FIG. 2 shows a schematic diagram of a memory according to an exemplary implementation. As shown in FIG. 2, the memory 103 includes a memory array 310, a plurality of bit lines (BL) 320, a plurality of word lines (WL) 330 and a peripheral circuit 340.

The memory array 310 includes a plurality of memory strings 311 arranged in an array above a substrate (not shown), and each memory string 311 extends vertically above the substrate.

Each memory string 311 includes a plurality of memory cells 312, and the plurality of memory cells 312 in each memory string 311 are vertically stacked above the substrate of memory array 310. Each memory cell 312 has the function of storing data. The stored data is determined by the number of electrons stored in the memory cell 312, and the number of electrons stored in the memory cell 312 can determine the threshold voltage of the memory cell 312. Therefore, the threshold voltage of the memory cell 312 can indicate the data stored therein. Wherein the memory cell 312 is a floating gate field effect transistor or a charge trap type field effect transistor. In some implementations, the memory cell 312 may have two possible storage states, e.g., the memory cell 312 may be a single level cell (SLC) storing data of one bit. For example, the threshold voltage corresponding to the first storage state “0” of the SLC may be in a first voltage range, and the threshold voltage corresponding to the first storage state “1” of the SLC may be in a second voltage range. In other implementations, the memory cell 312 may store at least data of two bits, e.g., the memory cell 312 is a multi-level cell (MLC), the MLC may store two bits per memory cell, or three bits per memory cell (also known as triple level cell (TLC)), or four bits per memory cell (also known as quad level cell (QLC)). Each MLC can be programmed to assume a range of possible nominal storage values.

Each memory string 311 further includes an upper select transistor 313 and a lower select transistor 314, and the upper select transistor 313 and the lower select transistor 314 are configured to activate the selected memory string when erasing, programming or erasing the memory cell. The upper select transistor 313 is also referred to as a top select gate (TSG), and the lower select transistor 314 is also referred to as a bottom select gate (BSG).

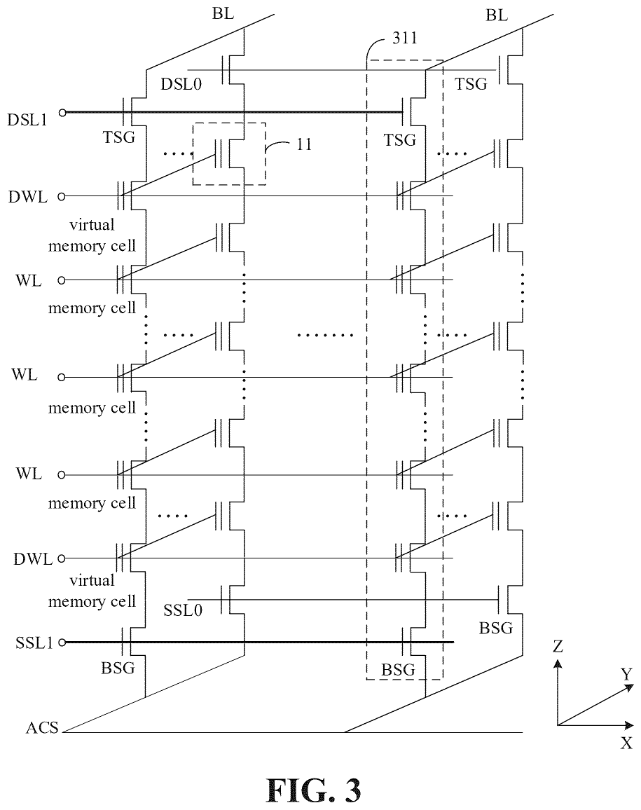

The memory 103 further includes a plurality of drain select lines (DSLs) 350, each DSL350 coupled to an upper select transistor 313 in at least one memory string 311, as shown in FIG. 2, and the upper select transistors 313 in the plurality of memory strings 311 at the same height or similar height from the substrate carrier surface are coupled to the same DSL350. Different DSLs are coupled to different memory strings 311, e.g., in the electrical structure diagram of a memory array according to an exemplary implementation shown in FIG. 3, DSL0 is coupled to TSGs of multiple memory strings 311 represented by thin solid lines, and DSL1 is coupled to TSGs of multiple memory strings 311 represented by thick solid lines.

The memory 103 also includes a plurality of source select lines (SSLs) 360, each SSL360 coupled to a lower select transistor 314 in at least one memory string 311, as shown in FIG. 2, and the lower select transistors 314 in the plurality of memory strings 311 at the same height or similar height from the substrate carrier surface are coupled to the same SSL360. Different SSLs are coupled to different memory strings 311. Taking SSL0 and SSL1 in FIG. 3 as an example, SSL0 is coupled to the BSGs of multiple memory strings 311 represented by thin solid lines, and SSL1 is coupled to the BSGs of multiple memory strings 311 represented by thick solid lines.

In other implementations, as shown in FIG. 2, each memory string 311 further includes a dummy cell, and there is at least one dummy cell on each memory string 311. FIG. 2 shows that the dummy cell is located between the memory cell 312 and the TSG and between the memory cell 312 and the BSG, while in other implementations, the dummy cell may also be located between the memory cells 312. Here, the position of the dummy cell in the memory string 311 is not limited. Multiple virtual memory cells of multiple memory strings 311 in the same layer are coupled to the same dummy word line (DWL). The virtual memory cell is optional. In some implementations, the memory string 311 may not include a virtual memory cell, in which case the memory 103 does not include a DWL.

One end of each memory string 311 is coupled to BL320. Taking FIG. 3 as an example, one BL may be coupled to multiple memory strings 311. The other end of each memory string 311 is coupled to an array common source (ACS) 370. For example, the other end of each memory string 311 is coupled to a semiconductor layer, and ACS370 is also coupled to the semiconductor layer, wherein the semiconductor layer may or may not be a substrate, e.g., in some implementations, the substrate may remain connected to the source, in which case the substrate is a semiconductor layer. In other implementations, the substrate is removed to form a new semiconductor layer, which serves as a source. Multiple memory strings 311 may be coupled to the same ACS370. The end of the memory string 311 coupled to BL320 may be referred to as the drain end of the memory string 311, and the end of the memory string 311 coupled to ACS370 may be referred to as the source end of the memory string 311.

As shown in FIG. 2, memory cells 312 in different memory strings 311 at a same height or similar height from the substrate carrying surface are in the same layer, multiple memory cells 312 in the same layer form a memory cell row 31a, e.g., the memory array 310 includes multiple memory cell rows, and multiple word lines 330 are coupled to the multiple memory cell rows respectively. All memory strings 311 in the memory array 310 that share the same set of word lines form a memory block 31b. As shown in FIG. 3, the source ends of each memory string 311 in the same memory block 31b are coupled to the same ACS. The source ends of each memory string 311 in the same memory block 31b are powered by the ACS.

Multiple memory blocks 31b in the memory array 310 may form a plane, for example, the memory array 310 includes multiple planes, and each plane includes multiple memory blocks 31b.

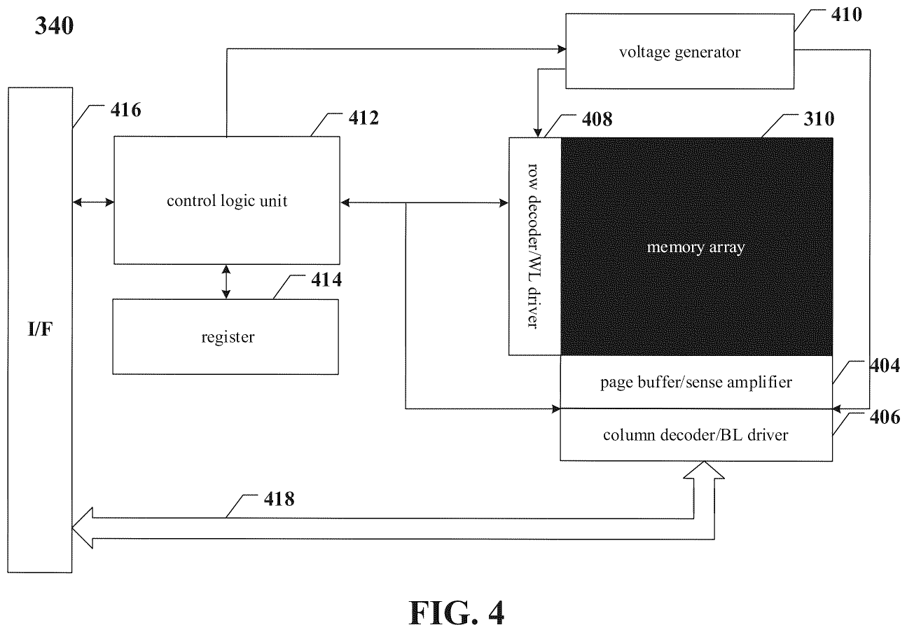

The peripheral circuit 340 includes various types of peripheral circuits formed with metal-oxide-semiconductor (MOS) technology. For example, FIG. 4 shows a structure diagram of a peripheral circuit according to an exemplary implementation. Peripheral circuit 340 as shown in FIG. 4 includes page buffer/sense amplifier 404, column decoder/bit line (BL) driver 406, row decoder/word line (WL) driver 408, voltage generator 410, control logic unit 412, register 414, interface (I/F) 416 and data bus 418. In some examples, additional peripheral circuits not shown may also be included in FIG. 4. The page buffer/sense amplifier 404 may be configured to read data from the memory array 310 and program (write) data to the memory array 310 according to control signals from the control logic unit 412. In an example, the page buffer/sense amplifier 404 may store a page of program data (written data) to be programmed into one page of the memory array 310. In another example, page buffer/sense amplifier 404 may perform a program verification operation to ensure that data has been correctly programmed into memory cell 312 coupled to the selected word line. In yet another example, page buffer/sense amplifier 404 may also sense a low power signal from bit line representing a data bit stored in memory cell 312 and amplify a small voltage swing to a recognizable logic level during a read operation. The column decoder/bit line driver 406 may be configured to be controlled by control logic unit 412 and to select one or more memory strings 311 by applying bit line voltage generated from voltage generator 410.

The row decoder/word line driver 408 may be configured to be controlled by control logic unit 412 and select/deselect memory block 31b of memory array 310 and select/deselect word line 330 of memory block 31b. The row decoder/word line driver 408 may also be configured to drive word line with word line voltage generated from the voltage generator 410. In some implementations, the row decoder/word line driver 408 may also select/deselect and drive DSL and SSL. As described in detail below, the row decoder/word line driver 408 is configured to perform erase operations on the memory cells 312 coupled to the selected word line(s). The voltage generator 410 may be configured to be controlled by the control logic unit 412, and generate word line voltage (e.g., read voltage, program voltage, pass voltage, local voltage, verification voltage, etc.), bit line voltage and source line voltage (e.g., the voltage of ACS) to be supplied to the memory array 310.

Control logic unit 412 may be coupled to each of the peripheral circuits 340 described above and configured to control operations of each of the peripheral circuits 340. Register 414 may be coupled to the control logic unit 412 and include status register, command register and address register for storing status information, command operation code (OP code) and command address configured to control operations of each of the peripheral circuits 340. The register 414 may also include at least one of a first register, a second register, a third register, a fourth register and a fifth register described below, wherein the first register, the second register, the third register, the fourth register and the fifth register may be the same register or different registers, and the functions of the first register, the second register, the third register, the fourth register and the fifth register will be described below and are not described in detail here.

Interface 416 may be coupled to control logic unit 412 and act as a control buffer to buffer control commands received from a host (not shown) and relay the control commands to control logic unit 412, and to buffer status information received from the control logic unit 412 and relay the status information to the host. The Interface 416 may also be coupled to column decoder/bit line driver 406 via data bus 418 and act as a data I/O interface and data buffer to buffer data and relay data to memory array 310 or buffer or relay data from memory array 310.

The memory block 31b in the memory array 310 supports an erase operation, and the erase operation includes multiple sub-operations such as a pre-program operation, an erase sub-operation, and an erase verification operation. The pre-program operation is a program operation performed on the memory cells in the memory block before erasing the memory block, for example, a program operation before erase operation, and the purpose of the pre-program operation is to set the threshold voltages of all memory cells in the memory block to a preset voltage so that all memory cells in the memory block have the same program depth. The erase sub-operation is configured to erase data stored in each memory cell in the memory block. The erase verification operation is configured to verify whether each memory cell in the memory block is successfully erased.

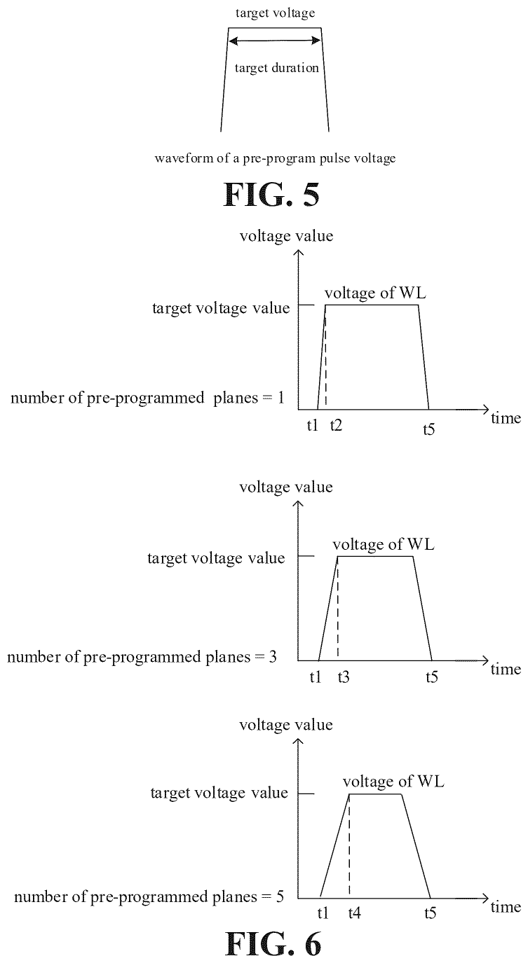

The pre-program operation includes: applying a pre-program pulse voltage to the WL coupled to each memory cell in the memory block to be erased, and applying a low voltage to the ACS (and/or BL) coupled to each memory string in the memory block, wherein the waveform of the pre-program pulse voltage is shown in FIG. 5, and after a target duration, the application of the pre-program pulse voltage and the low voltage is terminated. As shown in FIG. 5, the target duration is the total duration required to complete the performing of the pre-program operation, e.g., the total execution duration of the pre-program operation, the amplitude of the pre-program pulse voltage is the value of target voltage, and the pre-program pulse voltage is higher than the low voltage. During the application of the pre-program pulse voltage and the low voltage, the voltage difference between the WL and the ACS (and/or BL) coupled to the memory cells in the memory block can set the threshold voltage of each memory cell to a preset voltage, thereby programming each memory cell in the memory block to target program state, so that each memory cell in the memory block has the same program depth.

For an erase operation performed on any of memory blocks, during any of sub-operations of the erase operation, each time a suspend command for the erase operation is received, the memory 103 suspends the sub-operation (e.g., suspends the erase operation currently executed), and resumes the sub-operation (e.g., resumes to perform the suspended erase operation) when a resume instruction for the erase operation is received. It is to be noted that the suspend command in this application is configured to indicate the suspension of the erase operation, and the resume command in this application is configured to indicate the resume of the erase operation.

Taking the pre-program operation in the erase operation as an example, before the first performing of the pre-program operation, the target duration is used as the remaining duration of the pre-program operation, and the remaining duration refers to the duration for which the pre-program operation has not been performed. During the pre-program operation, each time a suspend command is received, the pre-program operation is immediately suspended to respond to the suspend command, and the difference between the remaining duration of the pre-program operation and the duration of the current performing of the pre-program operation is also used as a new remaining duration. When a resume command for the erase operation is received, the pre-program operation is resumed, e.g., the pre-program operation is performed according to the new remaining duration to implement the performing of the remaining pre-program operation until the remaining duration of the pre-program operation is equal to 0, which indicates that the duration for which the pre-program operation has been performed is equal to (e.g., reaches) the target duration, and the performing of pre-program operation is completed.

For example, during the pre-program operation, a pre-program pulse voltage is applied to the BL coupled to each memory cell in the memory block (hereinafter referred to as the BL coupled to the memory block), and during the application of the pre-program pulse voltage, the application of the pre-program pulse voltage is immediately terminated if a suspend command for the erase operation is received to implement the suspension of the pre-program operation. Assuming that the target duration is 204.8 microseconds (us), the remaining duration of the erase operation initially set is 204.8 us, and the duration of the pre-program pulse voltage applied currently is used as the duration of the pre-program operation performed currently, and assuming that the duration of the pre-program operation performed currently is 50 us, then 154.8 us=204.8 us-50 us is used as a new remaining duration of the erase operation.

After a resume command for the erase operation is received, the pre-program operation continues to be performed according to the new remaining duration of 154.8 us. For example, the pre-program pulse voltage is applied again to the BL coupled to the memory block, and during the process of applying the pre-program pulse voltage, if no new suspend command is received, the application of the pre-program pulse voltage is terminated after applying the pre-program pulse voltage for the remaining duration of 154.8 us, and the performing of the pre-program operation is completed; and during the process of applying the pre-program pulse voltage this time, if a new suspend command is received, the application of the pre-program pulse voltage is immediately terminated to implement the suspension of the pre-program operation. The difference between the remaining duration of the pre-program operation (e.g., 154.8 us) and the duration of the application of the pre-program pulse voltage (e.g., 80 us) this time is used as a new remaining duration (e.g., 74.8 us), and the pre-program operation continues to be performed according to the new remaining duration after receiving a resume command, and so on, until the remaining duration of the pre-program operation is equal to 0, which indicates that the performing of pre-program operation is completed. Wherein, performing the pre-program operation according to the remaining duration is equivalent to performing the remaining program operation.

Since the total duration of the performing of the pre-program operation (e.g., the target duration) is relatively short, if the pre-program operation is suspended multiple times, the peripheral circuit 340 needs to frequently provide the erase pulse voltage to the WL coupled to the memory block to be erased through the voltage generator 410 multiple times in a short time, resulting in a relatively short time for each erase pulse voltage to be provided, and causing the voltage on the WL may be lower than the target voltage value. For memory cells with lower threshold voltages, if the voltage on the WL coupled to these memory cells is lower than the target voltage value during the pre-program operation, the threshold voltage of these memory cells cannot reach the preset voltage, therefore the threshold voltages of the memory cells in the memory block are different and the program depths of the memory cells in the memory block to be erased are inconsistent after the pre-program operation is completed.

In some implementations, the plane in the pre-program operation process in the memory is referred to as a pre-programmed plane, wherein the plane in the pre-program operation process refers to a plane having a memory block in the pre-program operation, and at the same time, there may be multiple pre-programmed planes in the memory. For example, in the case that there is a requirement of erasing of multiple planes in the memory 103, the memory controller 102 sends an erase command to the memory 103, and the erase command carries the addresses of the multiple planes, the peripheral circuit 340 in the memory 103, after receiving the erase command, performs an erase operation on the memory blocks in the multiple planes based on the addresses of the multiple planes carried in the erase command, and during the erase operation, the pre-program operation is performed on the memory blocks in the multiple planes simultaneously, therefore the multiple Planes are all pre-programmed planes.

In the process of performing pre-program operations on multiple pre-programmed planes, the peripheral circuit 340 applies a pre-program pulse voltage to the WL coupled to each memory block in the multiple pre-programmed planes through the voltage generator 410, so that the word line voltage of the WL can rise to the target voltage value, however, the more pre-programmed planes there are, the greater the load of the voltage generator 410, and applying pre-program pulse voltage to the WL coupled to a large number of pre-programmed planes simultaneously makes the slope of the WL voltage rise smaller and the rising speed slower, therefore the time required for the WL voltage to rise to the target voltage value increases, for example, the rising period of the WL voltage is longer. As shown in FIG. 6, assuming that the pre-program pulse voltage is applied from time t1, in the case that the number of pre-program is equal to 1, 3, and 5, the voltage of WL rises to the target voltage value at time t2, time t3, and time t4, respectively, where t4>t3>t2>t1.

The longer the rising period of the WL voltage, the greater the probability of receiving a suspend command during the rising period, and once the suspend command is received during the rising period, the application of the pre-program pulse voltage will be immediately suspended, resulting in the voltage of WL lower than the target voltage value during the pre-program process (e.g., the voltage of WL is less likely to reach the target voltage). For memory cells with lower threshold voltages, the threshold voltage of these memory cells cannot reach the preset voltage if the voltage of the WL coupled to these memory cells cannot reach the target voltage value during the pre-program operation, so that the threshold voltages of the memory cells in the memory block are different and the program depths of the memory cells in the memory block to be erased are inconsistent after the pre-program operation is completed.

After the pre-program operation is completed, if the program depths of the memory cells in the memory block to be erased are inconsistent, the subsequent erase sub-operation of the memory block will cause the erase depths of the memory cells in the erased memory block to be inconsistent, and therefore, it is required to perform erase verification operations on the memory block multiple times to make the erase depths of the memory cells in the memory block consistent, which increases erase verification time and reduces the efficiency of erase verification, thereby reducing the reliability and performance of the memory. In some implementations, after the pre-program operation is completed, if the program depths of the memory cells in the memory block to be erased are inconsistent, even if an erase verification operation is performed after the erase sub-operation, the erase depths of the memory cells in the erased memory block may still be inconsistent, which will subsequently affect the data reading results after the memory cells are programmed, thereby reducing the reliability and performance of the memory.

Based on this, the present disclosure sets a first duration for the pre-program operation process, and during the pre-program operation of a certain memory block, the memory does not respond to a suspend command immediately if the suspend command is received, but responds to the suspend command only when the duration of the pre-program operation has reached the first duration, thereby the number of suspension of the pre-program operation is effectively controlled.

The first duration is the duration threshold for which the suspend command can be respond to during the pre-program operation, which may also be referred to as the suspend response time. The pre-program operation process may correspond to N first durations, where N is an integer greater than or equal to 1. Here, implementations of the present disclosure does not limit the number of first durations in the pre-program operation process.

In some implementations, the total duration (e.g., target duration) of the performing of the pre-program operation is divided into N time windows, for example, the pre-program operation process includes N time windows, and a total duration of first i time windows among the N time windows is the i-th first duration among the N first durations, and the first i time windows correspond to the i-th first duration, where 1≤i≤N, and i is an integer.

If N=1, the pre-program operation process lasts a time window, the number of first durations is one, and the first duration is equal to the target duration.

If N>1, each of the durations of first N−1 time windows among the N time windows is a second duration, and the duration of the last time window among the N time windows is a third duration, and the second duration is less than or equal to the first duration, and the third duration is less than or equal to the second duration, at this point, the target duration=(N−1)*the second duration+the third duration. For example, the target duration of the pre-program operation process is time sliced according to the second duration to obtain N time windows, e.g., each time the second duration elapses, the target duration is sliced once to obtain a time window, and after sliced N−1 times, the remaining duration of the target duration is a third duration, and the third duration is the last time window (e.g., the Nth time window). For example, assuming that the target duration is 204.8 us and the second duration is 90 us, the target duration is divided into three time windows, e.g., a first time window [0, 90] us, a second time window (90, 180] us, and a third time window (180, 204.8] us, wherein the third duration is the duration of the third time window, e.g., 64.8 us, and the pre-program operation process corresponds to 3 first durations, the first duration is the total duration of the first time window, e.g., 90 s; the second first duration is the total duration of the first time window and the second time window, e.g., 180 us; and the third first duration is the total duration of the first time window, the second time window, and the third time window, e.g., 204.8 us.

In some implementations, a first register may also be provided in the peripheral circuit of the memory, for example, the peripheral circuit includes a first register, and the first register is configured to store a second duration, so as to subsequently determine, based on the second duration, whether the duration for which the pre-program operation has been performed reaches the first duration.

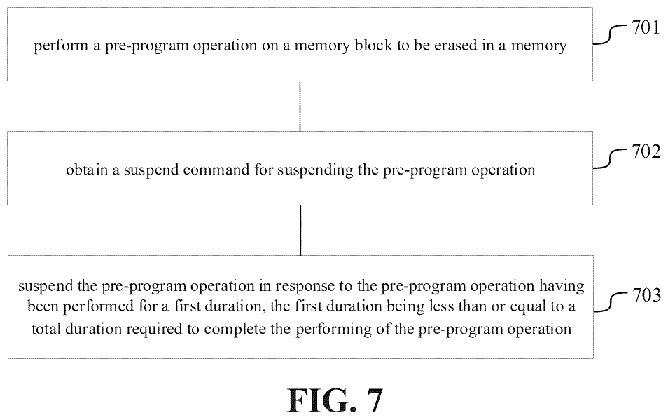

Based on the first duration and the pre-program operation process described above, in combination with FIG. 7, the flow of the operating method for memory provided in the present disclosure is described, where the memory may be the memory 103 described above, and the method may be performed by the peripheral circuit 340 in the memory 103. The method includes the following operations:

Operation 701. Perform a pre-program operation on a memory block to be erased in a memory.

Wherein the memory block is any of memory blocks in the memory array of the memory, and memory block and memory array may refer to the description above, which will not be described here.

Taking the memory system 100 in FIG. 1 as an example, in the case that there is a need to erase data in a memory block in the memory 103, the memory controller 102 sends an erase command to the memory 103, and the memory block is the memory block to be erased, the erase command carries the address of the memory block, and the peripheral circuit 340 in the memory 103 receives the erase command and performs an erase operation on the memory block based on the address in the erase command.

Alternatively, in the case that there is a need to erase at least one plane in the memory 103, the memory controller 102 sends an erase command to the memory 103, and the memory block in the at least one plane is the memory block to be erased, the erase command carries the address of the at least one plane, and the peripheral circuit 340 in the memory 103, after receiving the erase command, performs an erase operation on the memory blocks in the at least one plane based on the address of the at least one plane carried in the erase command.

For any of memory blocks to be erased, during the erase operation on the memory block, the peripheral circuit 340 first performs a pre-program operation on the memory block, and the performing of the pre-program operation may refer to the relevant description above, which will not be described here.

In some implementations, before performing a pre-program operation on the memory block, the peripheral circuit 340 also sets the parameters involved in the pre-program operation (e.g., the duration for which the pre-program operation has been performed, the remaining duration, and the target duration).

For example, the peripheral circuit 340 also includes a third register, a fourth register, and a fifth register, wherein the third register is configured to store the target duration of the pre-program operation.

The fourth register is configured to store a duration for which a pre-program operation has been performed, e.g., the fourth register stores the durations for which multiple pre-program operations have been performed, each of the durations for which a pre-program operation has been performed corresponds to a memory block, and before performing a pre-program operation on any of the memory blocks, the duration for which the pre-program operation corresponding to the memory block in the fourth register has been performed is set to 0 to prepare to time the duration for which the pre-program operation has been performed.

The fifth register is configured to store a remaining row duration of a pre-program operation, e.g., the fifth register stores remaining durations of multiple pre-program operations, each of the remaining durations of the multiple pre-program operations corresponds to a memory block, and before performing a pre-program operation on any of the memory blocks, the remaining duration of the pre-program operation corresponding to the memory block in the fifth register is set to the target duration to prepare to count down the remaining duration of the pre-program operation.

After the parameters involved in the pre-program operation of the memory block are set, the pre-program operation is performed on the memory block.

Operation 702. Obtain a suspend command for suspending the pre-program operation.

Wherein the suspend command refers to the suspend command for suspending the erase operation obtained in the pre-program operation.

Still taking the memory system 100 in FIG. 1 as an example, in the erase operation of the memory block, the memory controller 102 sends a suspend command to the memory 103 to indicate to suspend the erase operation if there is a need to perform other operations (such as program operation or data read operation) on the memory block. The peripheral circuit 340 in the memory 103 receives the suspend command, and determines whether the sub-operation of the erase operation currently performed on the memory block is a pre-program operation based on the suspend command, and if it is not a pre-program operation (e.g., it is an erase sub-operation or an erase verification operation), the sub-operation is immediately suspended to implement an immediate response to the suspend command. If the sub-operation of the erase operation currently performed on the memory block is a pre-program operation, it means that the suspend command is configured to suspend the pre-program operation, and the peripheral circuit 340 responds to the suspend command by performing the following operation 703.

Operation 703. Suspend the pre-program operation in response to the pre-program operation having been performed for a first duration, the first duration being less than or equal to a total duration required to complete the performing of the pre-program operation.

Wherein the total duration required to complete the performing of the pre-program operation is the target duration, and the pre-program operation corresponds to N first durations. When N=1, the first duration is equal to the target duration, and when N>1, the first duration used in this operation 703 is the first duration among the N durations that is greater than the duration for which the pre-program operation has been performed and has the smallest difference with the duration for which the pre-program operation has been performed, for example, greater than the duration for which the pre-program operation has been performed and has the shortest distance from the duration for which the pre-program operation has been performed. Wherein suspending the pre-program operation includes canceling the pre-program pulse voltage applied to the WL coupled to the memory block.

In the case where it is determined that the suspend command is configured to suspend the pre-program operation, the following operations A1 and A2 are performed in response to the suspend command.

Operation A1: Obtain the duration for which the pre-program operation has been performed.

Wherein the duration for which the pre-program operation has been performed refers to the duration for which the pre-program operation has actually been performed at current time.

In response to the suspend command, obtain the duration for which the pre-program operation has been performed this time before receiving the suspend command (referred to as the fourth duration), and the fourth duration is the duration for which the pre-program pulse voltage is applied to the BL coupled to the memory block this time before receiving the suspend command. The duration for which the pre-program operation corresponding to the memory block has been performed is queried from the fourth register, and the duration for which the pre-program operation corresponding to the memory block has been performed in the fourth register is summed with the fourth duration to obtain the duration for which the pre-program operation has actually been performed at current time.

Operation A2. Determine whether the pre-program operation has been performed for the first duration, based on the second duration and the duration for which the pre-program operation has been performed.

The second duration is obtained from the first register, and the duration for which the pre-program operation has been performed obtained in operation A1 is divided by the second duration to obtain the quotient P and remainder Q between the two durations. Wherein P is the number of time windows in which the pre-program operation has been performed, 0≤P≤N, when P=0, it means that the pre-program operation is currently performed in the first time window, and when P>0, it means that the pre-program operation has been performed for P time windows. The pre-program operation may be performed currently to the end of the P-th time window, and may also be performed in the (P+1)-th window. Q is the duration for which the pre-program operation has been performed in the current time window, 0≤Q<the second duration.

For example, when P=0 and Q>0, it means that the pre-program operation is performed currently in the first time window, and Q is the duration for which the pre-program operation has been performed in the first time window. When 0<P≤N and Q=0, it means that the pre-program operation has been performed to the end of the P-th time window, and the pre-program operation has been performed for P time windows. When 0<P<N and Q>0, it means that the pre-program operation is performed currently in the (P+1)-th time window, and Q is the duration for which the pre-program operation has been performed in the (P+1)-th time window.

Since the i-th first duration among N first durations is the total duration of first i time windows among the N time windows, the end time of each time window corresponds to a first duration. Based on this, when 0≤P<N and Q>0, it means that the pre-program operation is currently performed in the (P+1)-th time window, and has not been performed to the end of the (P+1)-th time window, the duration for which the pre-program operation has been performed is less than the (P+1)-th first duration, then it is determined that the pre-program operation has not been performed for the first duration, at this time, the first duration used for comparison is the P-th first duration. When 0<PS≤N and Q=0, it means that the pre-program operation has been performed to the end of the P-th time window, the duration for which the pre-program operation has been performed is equal to the P-th first duration, then it is determined that the pre-program operation has been performed for the first duration, at this time, the first duration used for comparison is the P-th first duration.

It can be seen that determine whether the duration for which the pre-program operation has been performed is equal to the first duration, for example, determine whether the pre-program operation has been performed for the first duration, e.g., if the duration for which the pre-program operation has been performed is equal to the first duration, it may be determined that the pre-program operation has been performed for the first duration; if the duration for which the pre-program operation has been performed is less than the first duration, it may be determined that the pre-program operation has not been performed for the first duration.

In response to the duration for which the pre-program operation has been performed being equal to the first duration, the pre-program operation is suspended. For example, when 0<PS≤N and Q=0, the duration for which the pre-program operation has been performed is equal to the P-th first duration, and the pre-program operation is suspended.

In response to the duration for which the pre-program operation has been performed being less than the first duration, continue to perform the pre-program operation, until the duration for which the pre-program operation has been performed is equal to the first duration, and suspend the pre-program operation. For example, when 0≤P<N and Q>0, the pre-program operation is performed currently in the (P+1)-th time window, then the pre-program operation continues to be performed, and the pre-program operation is continued to be performed to the end of the (P+1)-th time window, so that the duration for which the pre-program operation has been performed is equal to the (P+1)-th first duration, and the pre-program operation is suspended.

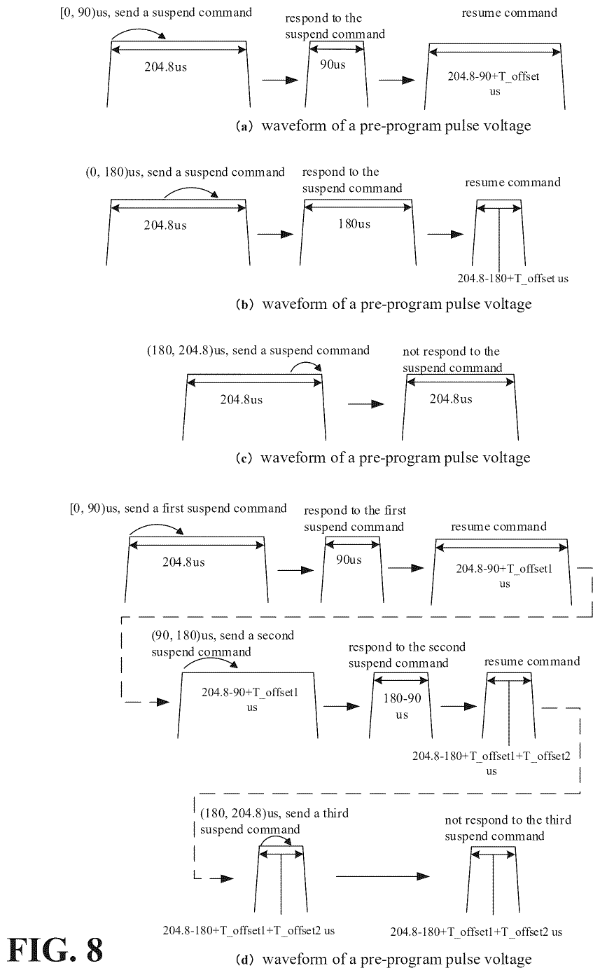

As shown in FIG. 8, taking the target duration 204.8 us and the second duration 90 us as an example, the pre-program operation includes three time windows, e.g., the first time window [0, 90] us, the second time window (90, 180] us, the third time window (180, 204.8] us, wherein the first time window corresponds to the 1st first duration of 90 us, the second time window corresponds to the 2nd first duration of 180 us, and the third time window corresponds to the 3rd first duration of 204.8 us.

Taking the waveform of erase pulse voltage shown in Figure (a) of FIG. 8 as an example, assuming that the program operation is performed currently in the first time window [0, 90] us, when the pre-program operation has been performed for any of durations in the interval [0, 90) us, if a suspend command is received from the memory controller 102, the peripheral circuit 340 does not immediately respond to the suspend command, but continues to perform the pre-program operation on the memory block until the duration for which the pre-program operation has been performed is equal to the corresponding first duration of 90 us, and then stops applying the pre-program pulse voltage (e.g., stops the pre-program pulse voltage applied to the WL coupled to the memory block during the pre-program operation) to suspend the pre-program operation and respond to the suspend command. For example, if a suspend command is received when the pre-program operation has been performed for 20 us, the quotient P and remainder Q between 20 us and the second duration 90 us are 0 and 20 respectively, which means that the pre-program operation is performed currently in the first time window, and the remaining duration of the pre-program operation in the first time window is 70 us=90 us−20 us, the pre-program operation is performed for another 70 us after a suspend command is received, so that the pre-program operation is performed for 90 us, and then the pre-program operation is suspended. Of course, if the pre-program operation has been performed for 90 us when the suspend command is received, the pre-program operation is suspended immediately to respond to the suspend command immediately.

Taking the waveform of erase pulse voltage shown in Figure (b) of FIG. 8 as an example, assuming that no suspend command is received when the program operation is performed in the first time window, and the program operation is performed currently in the second time window (90, 180] us, when the pre-program operation has been performed for any of durations in the interval (90, 180) us, if a suspend command is received from the memory controller 102, the peripheral circuit 340 does not respond to the suspend command immediately, and continues to perform the pre-program operation on the memory block until the pre-program operation has been performed for a duration equal to the corresponding first duration of 180 us, and then stops applying the pre-program pulse voltage to suspend the pre-program operation and respond to the suspend command. For example, if a suspend command is received when the pre-program operation has been performed for 150 us, the quotient P and remainder Q between 150 us and the second duration 90 us are 1 and 60 us respectively, which means that the pre-program operation is performed currently in the second time window, and the remaining duration of the pre-program operation in the second time window is 30 us=90 us-60 us, the pre-program operation is performed for another 30 us after receiving a suspend command, so that the pre-program operation is performed for 180 us, and then the pre-program operation is suspended. Of course, the pre-program operation is suspended immediately to respond to the suspend command immediately if the pre-program operation has been performed for 180 us when the suspend command is received.

Taking the waveform of erase pulse voltage shown in Figure (c) of FIG. 8 as an example, assuming that no suspend command is received when the program operation is performed in the first time window and the second time window, and the program operation is performed currently in the third time window (180, 204.8] us, when the pre-program operation has been performed for any of durations in the interval (180, 204.8) us, if a suspend command is received from the memory controller 102, the peripheral circuit 340 does not respond to the suspend command immediately, but continues to perform the pre-program operation on the memory block until the pre-program operation has been performed for a duration equal to the corresponding first duration of 180 us, and then stops applying the pre-program pulse voltage to suspend the pre-program operation and respond to the suspend command. For example, if a suspend command is received when the pre-program operation has been performed for 200 us, the quotient P and remainder Q between 200 us and the second duration 90 us are 2 and 20 us respectively, which means that the pre-program operation is performed currently in the third time window, and the remaining duration of the pre-program operation in the third time window is 60 us=90 us-20 us. It is to be noted that the actual remaining duration of the pre-program operation in the third time window is not 60 us, because the duration of the third time window is 24.8 us=204.8 us-180 us, and the actual remaining duration of the pre-program operation should be 4.8 us=24.8 us-20 us. In the case that Q is not equal to 0, the pre-program operation will not be suspended immediately, and the erase operation will continue to be performed according to the remaining duration of the pre-program operation in the fifth register, and after the pre-program operation is performed for the remaining duration, the duration for which the pre-program operation has been performed is equal to 204.8 us, and the pre-program pulse voltage applied to the WL coupled to the memory block is terminated, at this point, the performing of the pre-program operation is completed and the suspend command is responded to.

A suspend command may be received in each time window during the pre-program operation, and the above is described based on the example of a suspend command being received in one time window, while in other implementations, suspend commands may be received in multiple time windows during the pre-program operation, and for each suspend command, a suspend command is responded to at the end of the corresponding time window.

Taking the waveform of erase pulse voltage shown in Figure (d) of FIG. 8 as an example, assuming that a first suspend command is received from the memory controller 102 when the pre-program operation has been performed for a certain duration in the interval [0, 90) us, the pre-program operation continues to be performed until the duration for which the pre-program operation has been performed is equal to 90 us, and then the application of the pre-program pulse voltage is stopped to suspend the pre-program operation in response to the first suspend command. After the pre-program operation is resumed, the pre-program operation is performed in the second time window. Assuming that a second suspend command sent by the memory controller 102 is received when the pre-program operation has been performed for a certain duration in the interval (90, 180) us, the pre-program operation continues to be performed until the duration for which the pre-program operation has been performed is equal to 180 us, and then the application of the pre-program pulse voltage is stopped to suspend the pre-program operation in response to the second suspend command. After the pre-program operation is resumed again, the pre-program operation is performed in the third time window. Assuming that a third suspend command sent by the memory controller 102 is received when the pre-program operation has been performed for a certain duration in the interval (180, 204.8) us, the pre-program operation continues to be performed until the duration for which the pre-program operation has been performed is equal 204.8 us, and then the application of the pre-program pulse voltage is stopped to suspend the pre-program operation in response to the third suspend command.

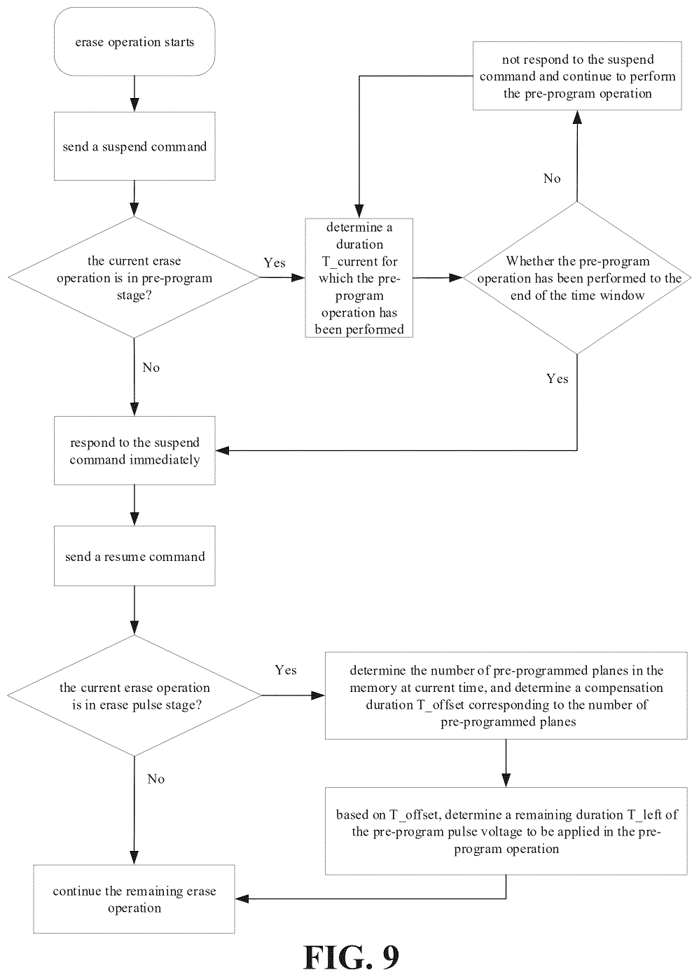

To facilitate understanding of the process in operations 701 to 703 described above, referring to FIG. 9, after starting to perform an erase operation on the memory block, during the erase operation, the memory controller 102 sends a suspend command to the memory 103. The peripheral circuit 340 in the memory 103 receives the suspend command, determines whether the current erase operation (e.g., the erase operation performed currently on the memory block) is in the pre-program stage (e.g., the pre-program operation process), and the current erase operation is suspended to respond to the suspend command immediately if the current erase operation is not in the pre-program stage (e.g., an erase sub-operation or an erase verification operation is performed currently). If the current erase operation is in the pre-program stage, a duration T_current for which the pre-program operation has been performed is determined, and based on T_current, it is determined whether the pre-program operation has been performed to the end of the current time window (e.g., it is determined whether the duration for which the pre-program operation has been performed is equal to the first duration), e.g., if T_current=the target duration T_prepgm, it is determined that the pre-program operation has been performed to the end of the current time window, and at this time, the time window in which the pre-program operation is performed currently is the last time window. As another example, if T_current=(P+1)*the second duration T_window, it is determined that the pre-program operation has been performed to the end of the current time window, and at this time, the time window in which the pre-program operation is performed currently is the (p+1)-th time window. As still another example, if T_current<T_prepgm and T_current≠(P+1)*T_window, it is determined that the pre-program operation has not been performed to the end of the current time window, and at this time, the time window in which the pre-program operation is performed currently is the (p+1)-th time window. In the case that the pre-program operation has been performed to the end of the current time window, the suspend command is responded to immediately. In the case that the pre-program operation has not been performed to the end of the current time window, the suspend command is not responded to immediately, and the pre-program operation (e.g., the current erase operation) continues to be performed until the pre-program operation is performed to the end of the time window, and then the suspend command is responded to immediately.

After the pre-program operation is suspended, the duration for which the pre-program operation has been performed in the fourth register is also updated. For example, in response to the pre-program operation having been performed for a first duration, the duration for which the pre-program operation corresponding to the memory block in the fourth register has been performed is updated to the first duration, to implement the timing of the duration for which the pre-program operation has been performed.

After the pre-program operation is suspended, the remaining duration of the pre-program operation in the fifth register is also updated. For example, after the pre-program operation is suspended, the duration for performing the pre-program operation is obtained, and the remaining duration of the pre-program operation corresponding to the memory block is queried from the fifth register, and the difference between the queried remaining duration of the pre-program operation and the duration for performing the pre-program operation is used as the latest remaining duration, and the remaining duration of the pre-program operation in the fifth register is updated to the latest remaining duration, to implement the countdown of the remaining duration of the pre-program operation.

In the method provided by the implementation in FIG. 7, during the process for performing a pre-program operation on a memory block to be erased, if a suspend command for suspending the pre-program operation is received, the pre-program operation is not suspended immediately in the case that the pre-program operation has not been performed for a certain duration (e.g., a first duration), and the pre-program operation is suspended to response to the suspend command only when the pre-program operation has been performed for a certain duration, and therefore the response time of the suspend command during the pre-program operation is increased, and the number of suspension of the pre-program operation is reduced, thereby improving the reliability and performance of the memory reduced due to multiple suspensions of the pre-program operation. The number of pre-program operation suspensions is reduced, so that the number of pre-programmed planes in the memory in the same duration may also be reduced, thereby alleviating the problem that program depths of memory cells in the memory block are inconsistent due to providing pre-program pulses to multiple pre-programmed planes, thus improving the reliability and performance of the memory.

If the first duration used when performing operation 703 is the target duration, then the pre-program operation has been completed after performing operation 703, and the peripheral circuit 340 may temporarily not perform the sub-operation following the pre-program operation in the erase operation (e.g., the erase sub-operation) on the memory block after performing the pre-program operation, and may perform the sub-operation following the pre-program operation after receiving the resume command.

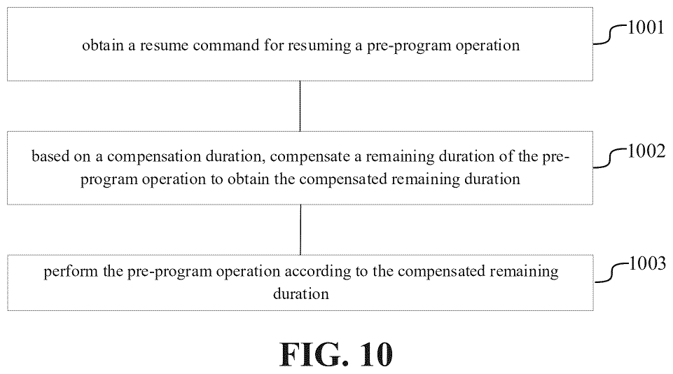

If the first duration used when performing operation 703 is less than the target duration, the pre-program operation has not been completed after performing the operation 703 described above, and the subsequent pre-program operation will enter the resume stage, the resume stage of the pre-program operation is described below in conjunction with FIG. 10.

FIG. 10 shows a flowchart of another operating method for memory according to an exemplary implementation, the memory may be the memory 103 described above, and the method may be performed by the peripheral circuit 340 in the memory 103. The method includes the following operations:

Operation 1001. Obtain a resume command for resuming a pre-program operation.

The resume command for resuming a pre-program operation refers to receiving a resume command for resuming an erase operation after suspending the pre-program operation in the case that the performing of the pre-program operation has not been completed.

Still taking FIG. 9 as an example, the memory controller 102 controls the memory 103 to perform other operations (e.g., a program operation or a data reading operation) after the peripheral circuit 340 responds to the suspend command, and the memory controller 102 sends a resume command for the erase operation to the memory 103 after the performing of the other operations are completed, the peripheral circuit 340 receives the resume command and determines whether the current erase operation is in the pre-program stage based on the resume command. If the current erase operation is not in the pre-program stage, the remaining erase operations continue to be performed, e.g., if the current erase operation is in the erase stage, the remaining erase sub-operations continue to be performed, and if the current erase operation is in the erase verification stage, the remaining erase verification operations continue to be performed. If the current erase operation is in the pre-program stage, the remaining pre-program operations (e.g., described below in operations 1002 and 1003) continue to be performed.

Operation 1002. Compensate a remaining duration of the pre-program operation based on a compensation duration to obtain a compensated remaining duration, wherein the remaining duration refers to the duration for which the pre-program operation has not been performed.

Wherein the remaining duration refers to the remaining duration of the pre-program operation after the most recent suspension of the pre-program operation. For example, after operation 703, the remaining duration of the updated pre-program operation is the remaining duration used in this operation 1002.

The compensation duration is configured to compensate for the remaining duration of the pre-program operation to achieve the purpose of compensating the target duration, so as to increase the total duration of the performing of the pre-program operation. The compensation duration is in positive correlation with the number of pre-programmed planes in the memory at current time, wherein the number of pre-programmed planes refers to the number of pre-programmed planes in the memory.

In some implementations, the positive correlation is represented by the correspondence between the number of pre-programmed planes and the compensation duration. As shown in Table 1 below, first compensation duration<second compensation duration<third compensation duration<fourth compensation duration<compensation duration 5.

TABLE 1

| Number of pre-programmed planes | compensation duration |
|---|---|
| 1 | first compensation duration |
| 2 | second compensation duration |
| 3 | third compensation duration |
| 4 | fourth compensation duration |
| 5 | compensation duration 5 |

In other implementations, the positive correlation is represented by a positive correlation function. Wherein the number of pre-programmed planes is an input parameter of the positive correlation function, and the compensation duration is an output parameter of the positive correlation function, and the positive correlation function is not limited here.

In some implementations, the peripheral circuit includes a second register, and the second register is configured to store the compensation duration. For example, the second register stores a correspondence between the number of multiple pre-programmed planes and compensation durations, or stores the positive correlation function.

After a resume command is received, the number of pre-programmed planes in the memory at current time is obtained. For example, the number of pre-programmed planes is determined based on the address in the erase command received in operation 701, and if the address in the erase command is the address of a plane, the total number of addresses in the erase command is used as the number of pre-programmed planes. If the address in the erase command is the address of at least one memory block, the plane to which the at least one memory block belongs is determined based on the address of the at least one memory block, and the total number of planes is determined as the number of pre-programmed planes.

After determining the number of pre-programmed planes in the memory at current time, the compensation duration is determined based on the number of pre-programmed planes in the memory at current time. For example, the compensation duration corresponding to the number of pre-programmed planes in the memory at current time is determined based on the positive correlation between the number of pre-programmed planes and the compensation duration.

Taking the positive correlation being the correspondence between the number of multiple pre-programmed planes and the compensation durations as an example, the compensation duration corresponding to the number of pre-programmed planes in the memory at current time is selected from the correspondence, e.g., taking Table 1 as an example, if the number of pre-programmed planes at current time is 2, the corresponding compensation duration is second compensation duration.

Taking the positive correlation being a positive correlation function as another example, the number of pre-programmed planes in the memory at current time is input as an input parameter to the positive correlation function, and the compensation duration output by the positive correlation function is used as the compensation duration corresponding to the number of pre-programmed planes.

After determining the compensation duration corresponding to the number of pre-programmed planes in the memory at current time, compensate a remaining duration of the pre-program operation based on a compensation duration to obtain the compensated remaining duration. For example, the remaining duration of the pre-program operation corresponding to the memory block is queried from the fifth register, the sum of the remaining duration and the compensation duration is used as the compensated remaining duration, and the remaining duration of the pre-program operation corresponding to the memory block in the fifth register is updated to the compensated remaining duration.

Taking FIG. 9 as an example, after a resume command is received, the number of pre-programmed planes in the memory at current time is determined in the case that the current erase operation is in the pre-program stage, and the compensation duration T_offset corresponding to the number of pre-programmed planes is determined based on the positive correlation described above, and the remaining duration T_left of the pre-program pulse voltage to be applied in the pre-program operation is determined based on T_offset, wherein T_left is the compensated remaining duration, e.g., the width of the remaining pre-program pulse voltage to be made, T_left=T_prepgm-T_Current+T_offset. After T_left is determined, the remaining erase operation continues to be performed according to T_left, and at this point, the remaining erase operation includes the remaining pre-program operation, and the remaining pre-program operation continues to be performed as in the following operation 1003.

Operation 1003. Perform the pre-program operation according to the compensated remaining duration.

For example, the compensated remaining duration is used as the duration for which the pre-program operation is to be performed, and the pre-program operation is performed for the compensated remaining duration, e.g., a pre-program pulse voltage is applied to the word line coupled to the memory block, and the application of the pre-program pulse voltage is terminated after the pre-program pulse voltage is applied for the compensated remaining duration, thereby implementing performing the pre-program operation according to the compensated remaining duration.

Taking Figure (a) in FIG. 8 as an example, assuming that the pre-program operation is suspended when it is performed for 90 us, at this point, the remaining duration of the pre-program operation=(204.8-90) us, and the compensation duration T_offset corresponding to the number of pre-programmed planes in the memory at current time (e.g., the number of current pre-programmed planes) is obtained after a resume command is received. Then the remaining duration is compensated to obtain the compensated remaining duration, which is (204.8−90+T_offset) us, and a pre-program pulse voltage is applied to the WL coupled to the memory block for the compensated remaining duration, then the application of the pre-program pulse voltage is terminated, and performing of the pre-program operation is completed.

Taking Figure (b) in FIG. 8 as another example, assuming that the pre-program operation is suspended when it is performed for 180 us, at this point, the remaining duration of the pre-program operation=(204.8−180) us, and the compensation duration T_offset corresponding to the number of current pre-programmed planes is obtained after a resume command is received. Then the remaining duration is compensated to obtain the compensated remaining duration, which is (204.8-180+T_offset) us, and a pre-program pulse voltage is applied to the WL coupled to the memory block for the compensated remaining duration, then the application of the pre-program pulse voltage is terminated, and performing of the pre-program operation is completed.

In other implementations, during the process for performing the pre-program operation according to the compensated remaining duration, the pre-program operation is suspended again according to operation 703 if a suspend command is received again, and in the resume stage of the pre-program operation, the process in the operations 1001 to 1003 described above is performed again until performing of the pre-program operation is completed.

Taking Figure (d) in FIG. 8 as another example, assuming that the pre-program operation is suspended when it is performed for 80 us in response to the first suspend command, at this point, the remaining duration of the pre-program operation=(204.8−90) us, and the compensation duration T_offset1 corresponding to the number of current pre-programmed planes is obtained after a first resume command is received. Then the remaining duration is compensated to obtain a first compensated remaining duration, a first remaining duration=(204.8−90+T_offset1) us, and an erase pulse voltage is applied to the WL coupled to the memory block according to the first remaining duration to implement the remaining pre-program operation. Assume that a second suspend command is received during the performing of the pre-program operation, the pre-program operation is suspended again when it is performed for 18 us in response to the second suspend command, and at this point, the remaining duration of the pre-program operation=(204.8−180+T_offset1) us, and the compensation duration T_offset2 corresponding to the number of current pre-programmed planes is obtained after a second resume command is received. Then the remaining duration is compensated to obtain a second compensated remaining duration, a second remaining duration=(204.8−180+T_offset1+T_offset2) us, and an erase pulse voltage is applied to the WL coupled to the memory block according to the second remaining duration to implement performing of the remaining pre-program operation. Assume that a third suspend command is received during performing of the pre-program operation, the pre-program operation will not be temporarily suspended since the program operation is performed in the last time window at this point. Rather, the application of the erase pulse voltage is terminated when the duration for which the erase pulse voltage is applied is equal to the second remaining duration, for example, when performing of the pre-program operation for the second remaining duration is completed. Then the performing of the pre-program operation is completed, and the third suspend command is responded to. If no suspend command is received during the performing of the pre-program operation, the application of the erase pulse voltage is also terminated when the duration for which the erase pulse voltage is applied is equal to the second remaining duration, and the performing of the pre-program operation is completed.

In the process of resuming the pre-program operation, the method provided by the implementation in FIG. 10 comprises: compensating the remaining duration of a pre-program operation by a compensation duration, and performing the pre-program operation according to the compensated remaining duration, which can increase the actual duration of performing of the pre-program operation, and in turn increase the application duration of the pre-program pulse voltage when the pre-program operation is performed according to the compensated remaining duration, so that the voltage of the word line coupled to the memory block can have enough time to rise and maintain at the target voltage value, thereby reducing or avoiding the problem that program depths of memory cells are inconsistent due to the voltage of the word line failing to reach the target voltage value during the pre-program operation, therefore improving reliability and performance of the memory. When resuming the pre-program operation, the remaining duration of the pre-program operation is compensated based on the number of pre-programmed planes in the memory at current time, which allows for differential compensation for the remaining duration of the pre-program operation at different times, and the application duration of the pre-program pulse voltage can be increased when performing the pre-program operation according to the compensated remaining duration, which allows for enough time for the voltage of the word line coupled to the memory block to rise and maintain at the target voltage value, so that the memory cells in the memory block can reach the same program depth, therefore the problem that program depths of memory cells in a memory block are inconsistent due to providing pre-program pulse voltages to multiple pre-programmed planes simultaneously may be avoided, thereby further improving reliability and performance of the memory.

In other implementations, the erase operation is suspended after performing operation 703, and if a resume command is received subsequently (such as operation 1001), the operations 1002 and 1003 described above will not be performed, and instead the pre-program operation is performed according to the current remaining duration of the pre-program operation.

In other implementations, during the pre-program operation, if a suspend command is received (such as operation 702), the pre-program operation is suspended immediately to respond to the suspend command immediately without determining whether the pre-program operation has been performed for the first duration, and the pre-program operation is resumed according to the process in operations 1001 to 1003 described above.

The above description is only an optional implementation of the present disclosure, and is not intended to limit the present disclosure, and any modification, equivalent replacement and improvement, etc., made within the spirit and principles of the present disclosure shall be included within the protection scope of the present disclosure.

What is claimed is:

1. An operating method for memory, comprising:
performing a pre-program operation on a memory block to be erased in a memory;
obtaining a suspend command for suspending the pre-program operation; and
suspending the pre-program operation in response to the pre-program operation having been performed for a first duration, the first duration being less than or equal to a total duration required to complete the performing of the pre-program operation.

2. The method of claim 1, wherein the suspending the pre-program operation in response to the pre-program operation having been performed for a first duration comprises:
suspending the pre-program operation in response to a duration for which the pre-program operation having been performed being equal to the first duration; and
continuing to perform the pre-program operation in response to the duration for which the pre-program operation having been performed being less than the first duration, until the duration for which the pre-program operation has been performed is equal to the first duration, and suspending the pre-program operation.

3. The method of claim 1, wherein a process of the pre-program operation corresponds to N first durations, N being an integer greater than or equal to 1.

4. The method of claim 3, wherein the process of the pre-program operation includes N time windows, and a total duration of first i time windows among the N time windows comprise a first duration, i being an integer greater than or equal to 1 and less than or equal to N.

5. The method of claim 4, wherein if N is greater than 1, each of the durations of first N−1 time windows among the N time windows comprise a second duration, and the duration of the last time window among the N time windows comprise a third duration, and the third duration is less than or equal to the second duration.

6. The method of claim 5, wherein after the obtaining the suspend command for suspending the pre-program operation, the method further comprises:
determining whether the pre-program operation has been performed for the first duration, based on the second duration and the duration for which the pre-program operation has been performed.

7. The method of claim 1, wherein after the suspending the pre-program operation, the method further comprises:
obtaining a resume command for resuming the pre-program operation;
compensating a remaining duration of the pre-program operation based on a compensation duration to obtain the compensated remaining duration, wherein the remaining duration refers to the duration for which the pre-program operation has not been performed; and
performing the pre-program operation according to the compensated remaining duration.

8. The method of claim 7, wherein before the compensating a remaining duration of the pre-program operation based on a compensation duration to obtain the compensated remaining duration, the method further comprises:
determining the compensation duration based on a number of pre-programmed planes of the memory at current time, wherein the number of pre-programmed planes refers to a number of planes in the memory that are in a process of the pre-program operation, and the planes include one or more memory blocks.

9. The method of claim 8, wherein the number of pre-programmed planes is in positive correlation with compensation time.

10. A memory comprising a memory block and a peripheral circuit, wherein the memory block configured to store data, the memory block is coupled to the peripheral circuit through a word line, and the peripheral circuit is configured to:
perform a pre-program operation on a memory block to be erased in the memory;
obtain a suspend command for suspending the pre-program operation; and
suspend the pre-program operation in response to the pre-program operation having been performed for a first duration, the first duration being less than or equal to a total duration required to complete the performing of the pre-program operation.

11. The memory of claim 10, wherein the peripheral circuit is further configured to:
suspend the pre-program operation in response to a duration for which the pre-program operation having been performed being equal to the first duration; and
continue to perform the pre-program operation in response to the duration for which the pre-program operation having been performed being less than the first duration, until the duration for which the pre-program operation has been performed is equal to the first duration, and suspend the pre-program operation.

12. The memory of claim 10, wherein a process of the pre-program operation corresponds to N first durations, N being an integer greater than or equal to 1.

13. The memory of claim 12, wherein a process of the pre-program operation includes N time windows, and a total duration of first i time windows among the N time windows comprise a first duration, i being an integer greater than or equal to 1 and less than or equal to N.

14. The memory of claim 13, wherein if N is greater than 1, each of the durations of first N−1 time windows among the N time windows comprise a second duration, and the duration of the last time window among the N time windows comprise a third duration, and the third duration is less than or equal to the second duration.

15. The memory of claim 14, wherein the peripheral circuit is further configured to:
determine whether the pre-program operation has been performed for the first duration, based on the second duration and the duration for which the pre-program operation has been performed.

16. The memory of claim 14, wherein the peripheral circuit includes a first register, and the first register is configured to store the second duration.

17. The memory of claim 10, wherein the peripheral circuit is further configured to:
obtain a resume command for resuming the pre-program operation;
compensate a remaining duration of the pre-program operation based on a compensation duration to obtain the compensated remaining duration, wherein the remaining duration refers to the duration for which the pre-program operation has not been performed; and
perform the pre-program operation according to the compensated remaining duration.

18. The memory of claim 17, wherein the peripheral circuit includes a second register, and the second register is configured to store the compensation duration.

19. The memory of claim 17, wherein the peripheral circuit is further configured to:
determine the compensation duration based on a number of pre-programmed planes of the memory at current time, wherein the number of pre-programmed planes refers to a number of planes in the memory that are in a process of the pre-program operation, the planes include one or more memory blocks, and the number of pre-programmed planes is in positive correlation with compensation time.

20. A memory system comprising a memory controller and a memory, wherein the memory controller is coupled to the memory and configured to control the memory,
the memory comprises a memory block and a peripheral circuit, the memory block is configured to store data, the memory block is coupled to the peripheral circuit through a word line, and the peripheral circuit is configured to:
perform a pre-program operation on a memory block to be erased in the memory;
obtain a suspend command for suspending the pre-program operation; and
suspend the pre-program operation in response to the pre-program operation having been performed for a first duration, the first duration being less than or equal to a total duration required to complete the performing of the pre-program operation.
